(19) United States
(12) Patent Application Publication
(10) Pub. No.: US 2023/0129699 A1
(43) Pub. Date: Apr. 27, 2023

(54) IC PACKAGE WITH INTERFACE REGION

(71) Applicant: TEXAS INSTRUMENTS INCORPORATED, DALLAS, TX (US)

(72) Inventors: Rafael Jose Lizares Guevara, Makati Metro Manila (PH); John Carlo Cruz Molina, Bataan (PH)

(21) Appl. No.: 17/508,009

(22) Filed: Oct. 22, 2021

(51) Int. Cl. H01L 23/16; H01L 23/31; H01L 23/00; H01L 21/48; H01L 21/56

(52) U.S. Cl. CPC H01L 23/16; H01L 23/3157; H01L 24/48; H01L 21/4814; H01L 21/56; H01L 2224/48247; H01L 23/3736

(57) ABSTRACT

An integrated circuit (IC) package includes a die having a interface region situated on a surface of the die. The interface region is configured to be exposed to an environment of the IC package. The IC package also includes a metal wall mounted on the surface of the die that circumscribes the interface region and extends from the surface of the die to a wall height. The metal wall has a first region and a second region that is stacked on the first region, the first region having a first thickness and the second region having a second thickness. The second thickness is greater than the first thickness. The IC package further includes a molding encasing a remaining portion of the die. The molding has a height that extends from the surface of the die to a level that is less than the wall height of the metal wall.

### TECHNICAL FIELD

This description relates to an integrated circuit (IC) package that includes an interface region exposed to an environment of the IC package.

### BACKGROUND

A semiconductor package is a metal, plastic, glass, or ceramic casing containing one or more discrete semiconductor devices or integrated circuits. Individual components are fabricated on semiconductor wafers (commonly silicon) before being diced into die, tested, and packaged. The package provides conductive members (e.g., leads) that enable connecting to an external environment, such as a printed circuit board (PCB). Moreover, the package provides protection against threats such as mechanical impact, chemical contamination, and unintended light exposure. Also, the package facilitates the dissipation of heat produced by the device, with or without the aid of a heat spreader. There are thousands of package types in use.

Some semiconductor packages, such as integrated circuit (IC) chips are molded out of an epoxy plastic that provides adequate protection of the semiconductor devices, and mechanical strength to support the connections (e.g., leads) and handling of the semiconductor package.

### SUMMARY

A first example relates to an integrated circuit (IC) package that includes a die having a interface region situated on a surface of the die. The interface region is configured to be exposed to an environment of the IC package. The IC package also includes a metal wall mounted on the surface of the die that circumscribes the interface region and extends from the surface of the die to a wall height. The metal wall has a first region and a second region that is stacked on the first region. The first region has a first thickness and the second region has a second thickness, the second thickness being greater than the first thickness. The IC package further includes a molding encasing a remaining portion of the die. The molding has a height that extends from the surface of the die to a level that is less than the wall height of the metal wall.

A second example relates to a method for forming an IC package. The method includes etching a pattern in a layer of resist overlaying a surface of a die. The pattern includes an etched cavity circumscribing an interface region on the surface of the die. The etched cavity extends from the surface of the die to a first height. The method also includes depositing metal in the etched cavity to form a metal wall circumscribing the interface region of the die. The metal wall has a first region having a first width. The first region extends from the surface of the die to the first height. The metal wall has a second region stacked on the first region, the second region having a second width greater than the first width and the second region extending from the first height to a second height. The method includes stripping the resist from the surface of the die and applying a mold to encase the die, such that the interface region is exposed to an environment. The mold extends from the surface of the die to a height less than the second height of the metal wall.

### BRIEF DESCRIPTION OF THE DRAWINGS

FIG. 1 illustrates a diagram of a cross-sectional view of an example of an integrated circuit (IC) package with an interface region and a metal wall circumscribing the interface region.

FIG. 2 illustrates an expanded overhead view and an expanded cross-sectional view of the IC package of FIG. 1.

FIG. 3 illustrates a diagram of a cross-sectional view of another example of an IC package with an interface region and a metal wall circumscribing the interface region.

FIG. 4 illustrates an expanded overhead view and an expanded cross-sectional view of the IC package of FIG. 3.

FIG. 5 illustrates a first stage of an example method for forming an IC package.

FIG. 6 illustrates a second stage of the example method for forming the IC package.

FIG. 7 illustrates a third stage of the example method for forming the IC package.

FIG. 8 illustrates a fourth stage of the example method for forming the IC package.

FIG. 9 illustrates a fifth stage of the example method for forming the IC package.

FIG. 10 illustrates a sixth stage of the example method for forming the IC package.

FIG. 11 illustrates a seventh stage of the example method for forming the IC package.

FIG. 12 illustrates an eighth stage of the example method for forming the IC package.

FIG. 13 illustrates a first stage of another example method for forming the IC package.

FIG. 14 illustrates a second stage of the other example method for forming the IC package.

FIG. 15 illustrates a third stage of the other example method for forming the IC package.

FIG. 16 illustrates a fourth stage of the other example method for forming the IC package.

FIG. 17 illustrates a fifth stage of the other example method for forming the IC package.

FIG. 18 illustrates a sixth stage of the other example method for forming the IC package.

FIG. 19 illustrates a seventh stage of the other example method for forming the IC package.

FIG. 20 illustrates an eighth stage of the other example method for forming the IC package.

FIG. 21 illustrates a ninth stage of the other example method for forming the IC package.

FIG. 22 illustrates a flowchart of an example method for forming an IC package.

### DETAILED DESCRIPTION

This description relates to an integrated circuit (IC) package with an interface exposed to an environment of the IC package, and a method for making the IC package. The IC package includes a die with the interface region situated on a surface of the die. In some examples, the IC package is a sensor (e.g., a temperature sensor or a pressure sensor), and the interface region is exposed to the environment of the IC package to detect conditions of the environment (e.g., detect the temperature or pressure in the environment). In other examples, the IC package is an output device (e.g., a light emitting device), where light (or other output) is injected into the environment from the interface region.

The IC package has a metal wall mounted on the surface of the die that circumscribes the interface region and extends from the surface of the die to a wall height. The metal wall is formed of copper or other metal. The metal wall includes a first region and a second region that is stacked on the first region. The first region has a first thickness and the second region has a second thickness, the second thickness being greater than the first thickness. As an example, a cross section of the wall has a mushroom shape or nail shape. A molding encases a remaining portion of the die. The molding has a height that extends from the surface of the die to a level that is less than the wall height of the metal wall. The metal wall ensures that during fabrication of the IC package, the molding does not flow over the metal wall and obstruct the interface region from viewing the environment of the IC package.

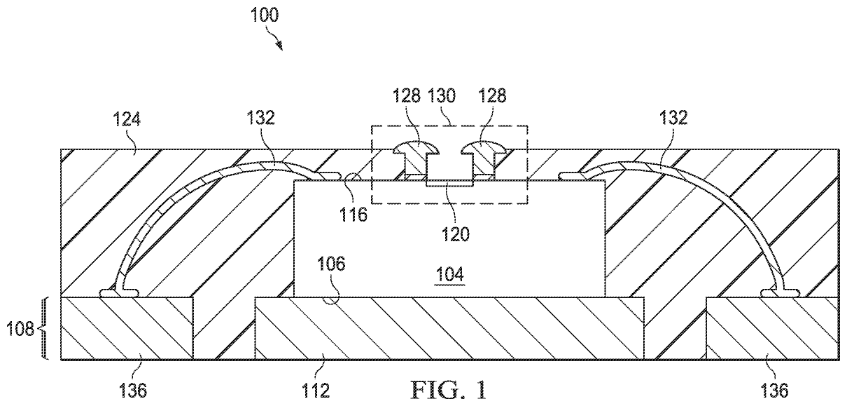

FIG. 1 illustrates a cross-section of an IC package 100. The IC package 100 is employable as a sensor (e.g., a temperature sensor, a pressure sensor, etc.) or as an optical device (e.g., a light emitting device). The IC package 100 includes a die 104 that has a first surface 106 mounted on an interconnect 108 (e.g., a lead frame). More particularly, the first surface 106 of the die 104 is mounted on (e.g., adhered to) a die pad 112 of the interconnect 108.

The die 104 includes a second surface 116 that opposes the first surface 106. The second surface 116 of the die 104 includes an interface region 120 that is exposed to an environment of the IC package 100. Stated differently, the interface region 120 is situated on the second surface 116 of the die 104. The IC package 100 is encased in a molding 124 formed of plastic (or other non-conductive material). The interface region 120 is circumscribed by a metal wall 128 that provides a barrier between the interface region 120 of the die 104 and the molding 124. The metal wall 128 is formed of a metallic material, such as copper.

The interface region 120 enables the IC package 100 to sense or interact with the environment in which the IC package 100 is designed to operate. A portion of the interface region 120 has an unobstructed view of the environmental external to the IC package 100. In some examples, the interface region 120 includes circuitry for sensing a temperature or pressure of the environment. In other examples, the interface region 120 includes circuitry for injecting an optical output (e.g., a light source) into the environment.

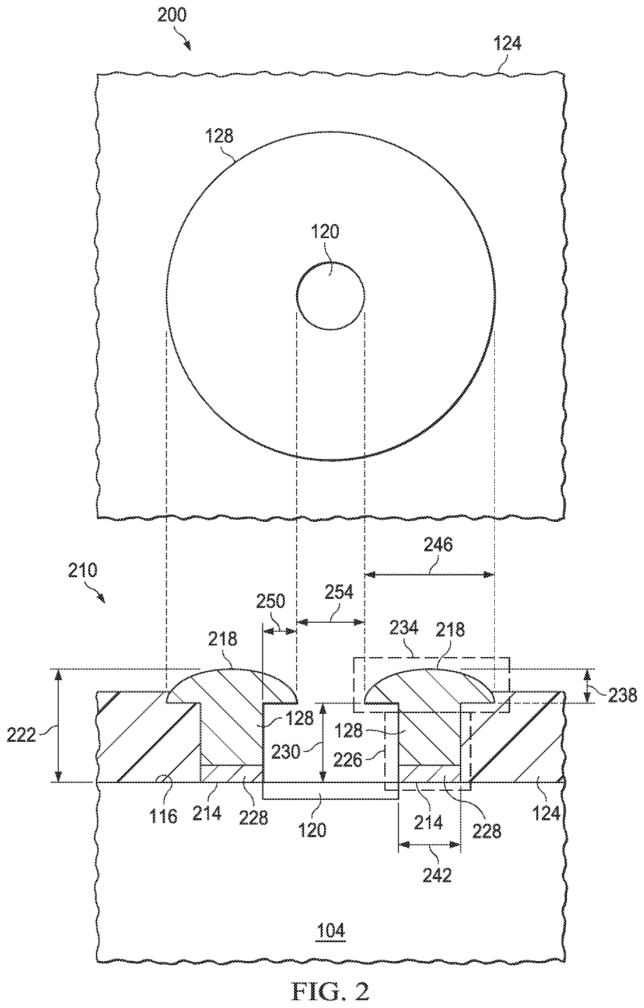

FIG. 2 illustrates an overhead view 200 and an expanded cross sectional view 210 of a region 130 of FIG. 1. Thus, for purposes of simplification of explanation, FIGS. 1-3 employ the same reference numbers to denote the same structures. Guidelines between the overhead view 200 and the expanded cross sectional view 210 are included to improve readability.

As illustrated in the overhead view 200, the interface region 120 is circumscribed by the metal wall 128. Moreover, as illustrated in the overhead view 200, the metal wall 128 acts as a barrier to prevent molding 124 from obstructing the view of the interface region 120.

As illustrated in the expanded cross sectional view 210, the metal wall 128 has a first end 214 mounted on the second surface 116 of the die 104. The metal wall 128 has a wall height corresponding to a distance between the first end 214 proximal to the second surface 116 of the die 104 and a second end 218 that is distal to the second surface 116 of the die 104, as indicated by the arrow 222. In some examples, the wall height is about 150 micrometers (μm). Unless otherwise stated, in this description, ‘about’ preceding a value means+/−10 percent of the stated value. Moreover, the metal wall 128 has a first region 226 that extends from the second surface 116 of the die 104 to a first height, as indicated by arrows 230. The metal wall 128 has a second region 234 that extends from the first height to the second end 218 by a second height, as indicated by arrows 238. The first height is about 90 μm and the second height is about 60 μm, such that the second height of the metal wall 128 combined provide the overall height of the metal wall 128.

The first region 226 has a first width (e.g., about 80 μm), as indicated by the arrows 242, and the second region 234 has a second width (e.g., about 120 130 μm), as indicated by the arrows 246. That is, the second width is greater than the first width. A portion of the first region 226 that is most proximal (closest) to the second surface 116 is formed of remnants of a seed layer 228. Thus, the second region 234 includes a portion that extends beyond the first region 226 by about 40 μm on each side, as indicated by the arrows 250. Accordingly, a portion of the second region 234 of the metal wall 128 overhangs the interface region 120 of the die 104. The second region 234 of the metal wall 128 has a semicircle cross-section shape, such that a cross section of the metal wall 128 has a mushroom shape. The molding 124 has a height that extends from the second surface 116 of the die 104 to a height less than the height of the second region 234. In some examples, the molding has a height equal to or greater than the height of the first region 226.

As illustrated by the overhead view 200, the metal wall 128 has a ring shape (e.g., a circular cross-section) in the provided example. However, in other examples, the metal wall 128 has a different shape, such as an oval or rectangular cross section. In examples where the metal wall 128 has a ring shape, the metal wall 128 has a diameter of 55 μm or more, as indicated by the arrows 254 of the expanded cross sectional view 210.

Referring back to FIG. 1, wire bonds 132 extend from the second surface 116 of the die 104 to pads 136 of the interconnect 108. The pads 136 enable the IC package 100 to communicate with other circuit components. Accordingly, the wire bonds 132 electrically couple the second surface 116 of the die 104 to the pads 136 of the interconnect 108. By including the metal wall 128 with the second region 234 of FIG. 2, during fabrication, the molding 124 is impeded from flowing over the metal wall 128. Impeding the molding 124 from breaching the metal wall 128 in turn prevents the molding 124 from obstructing a view of the interface region 120 of the die 104. Accordingly, an overall performance of the IC package 100 is improved relative to one with a shorter wall that allows the molding 124 to flow over a corresponding interface region.

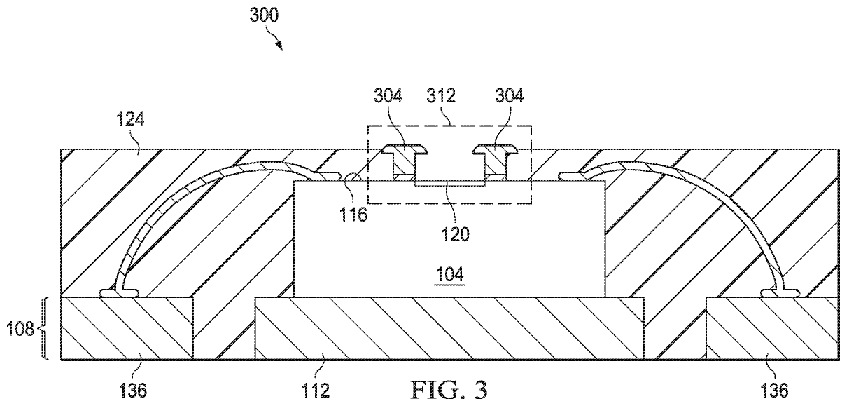

FIG. 3 illustrates a cross-section of an alternative IC package 300. The IC package 300 is employable as a sensor (e.g., a temperature sensor, a pressure sensor, etc.) or as an optical device (e.g., a light emitting device). The IC package 300 is similar to the IC package 100 of FIG. 1. Thus, for purposes of simplification of explanation, FIGS. 1 and 3 employ the same reference numbers to denote the same structures. Moreover, some reference numbers are not re-introduced. The IC package 300 includes the die 104 that is mounted on (e.g., adhered to) the die pad 112 of the interconnect 108. The die 104 includes the second surface 116 that opposes the first surface 106. The second surface 116 of the die 104 includes the interface region 120 that is exposed to an environment of the IC package 100. The IC package 300 is encased in a molding 124 formed of plastic (or other non-conductive material).

The interface region 120 is circumscribed by a metal wall 304 that provides a barrier between the interface region 120 of the die 104 and the molding 124. The metal wall 304 is formed of a metallic material, such as copper.

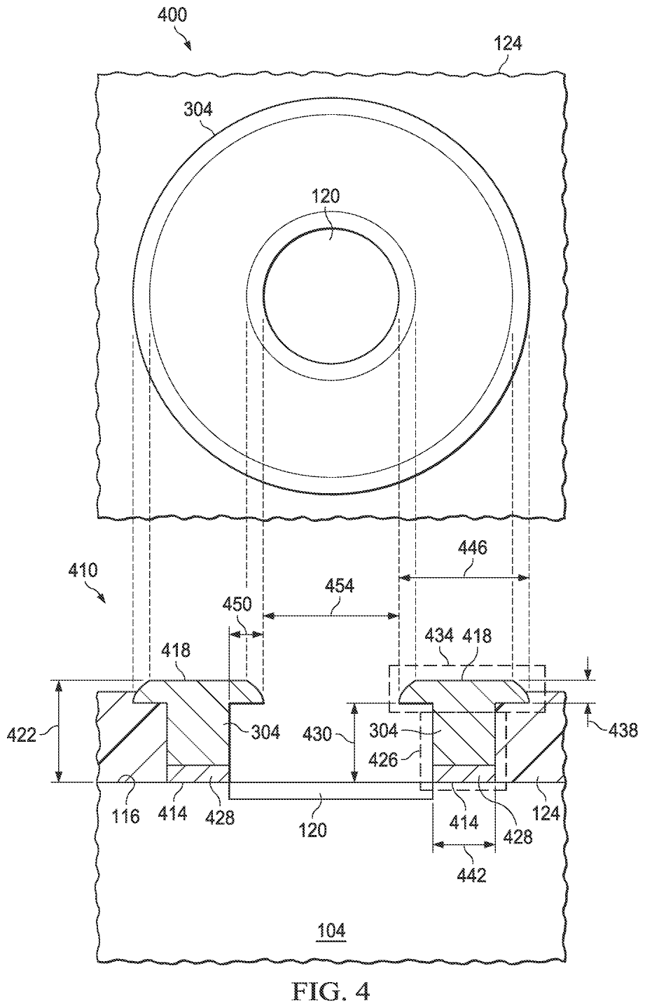

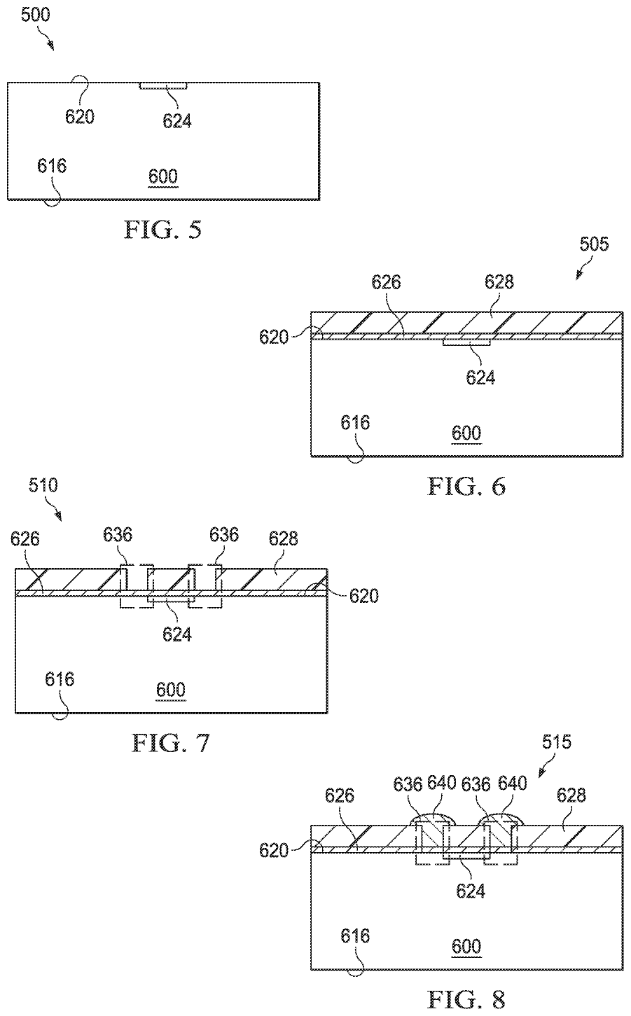

FIG. 4 illustrates an overhead view 400 and an expanded cross sectional view 410 of a region 312 of FIG. 3. Thus, for purposes of simplification of explanation, FIGS. 4 and 5 employ the same reference numbers to denote the same structures. Guidelines between the overhead view 400 and the expanded cross sectional view 410 are included to improve readability.

As illustrated in the overhead view 400, the interface region 120 is circumscribed by the metal wall 128. Moreover, as illustrated in the overhead view 400, the metal wall 128 acts as a barrier to prevent the molding 124 from obstructing the view of the interface region 120.

As illustrated in the expanded cross sectional view 410, the metal wall 304 has a first end 414 mounted on the second surface 116 of the die 104. The metal wall 304 has a wall height corresponding to a distance between the first end 414 proximal to the second surface 116 of the die 104 and a second end 418 that is distal to the second surface 116 of the die 104, as indicated by the arrow 422. In some examples, the wall height is about 130 micrometers (μm). Moreover, the metal wall 304 has a first region 426 that extends from the second surface 116 of the die 104 to a first height, as indicated by arrows 430. The metal wall 304 has a second region 434 that extends from the first height to the second end 418 by a second height, as indicated by arrows 438. The first height is about 90 μm and the second height is about 40 μm, such that the second height of the metal wall 304 combined provide the overall height of the metal wall 304.

The first region 426 has a first width (e.g., about 80 μm), as indicated by the arrows 442 and the second region 434 has a second width (e.g., about 120-130 μm), as indicated by the arrows 446. That is, the second width is greater than the first width. A portion of the first region 426 that is most proximal (closest) to the second surface 116 is formed of remnants of a seed layer 428. That is, the second width is greater than the first width. Thus, the second region 434 includes a portion that extends beyond the first region 426 by about 40 μm on each side, as indicated by the arrows 450. Thus, a portion of the second region 434 of the metal wall 304 overhangs the interface region 120 of the die 104. The second end 418 of the second region 434 has a planer surface, such that a cross section of the metal wall 128 has a shape similar to a nail.

As illustrated by the overhead view 400, the metal wall 304 has a ring shape (e.g., a circular cross-section) in the provided example. However, in other examples, the metal wall 304 has a different shape, such as an oval or rectangular cross section. In examples where the metal wall 304 has a ring shape, the metal wall 304 has a diameter of 55 μm or more, as indicated by the arrows 454 of the expanded cross sectional view 210.

Referring back to FIG. 3, by including the metal wall 304 with the second region 434 of FIG. 2, during fabrication, the molding 124 is impeded from flowing over (breaching) the metal wall 304. Impeding the molding 124 from breaching the metal wall 304 in turn prevents the molding 124 from obstructing a view of the interface region 120 of the die 104. Accordingly, an overall performance of the IC package 300 is improved relative to one with a shorter wall that allows the molding 124 to flow over a corresponding interface region.

FIGS. 5-12 illustrate methods for forming an IC package, such as the IC package 100 of FIG. 1. For purposes of simplification of explanation, FIGS. 5-12 employ the same reference numbers to denote the same structure.

In a first stage, as illustrated in FIG. 5, at 500, a die 600 is provided. In some examples, the die 600 is implemented with the die 104 of FIGS. 1-4. More particularly, a first side 616 of the die 600 is mountable on a die pad of an interconnect (e.g., a lead frame). A second side 620 of the die 600 includes an interface region 624 configured to interact with an environment of the IC package. In some examples, the die 600 is a sensor, and the interface region 624 enables the die 600 to sense the environment. In other examples, the interface region 624 provides light to the environment.

In a second stage, as illustrated in FIG. 6, at 505, a seed layer 628 for growing metal (e.g., copper) is deposited on the second side 620 of the die 600 (e.g., with a spudder deposition operation). Also, at 505, a layer of resist 628 (e.g., photoresist) is applied to the second side 620 of the die 600, overlaying the seed layer 628. In a third stage, as illustrated in FIG. 7 at 510, the resist 628 is etched to provide a cavity 636 for a metal wall. The cavity 636 circumscribes the interface region 624. Thus, in some examples, the cavity 636 has a circular shape.

In a fourth stage, as illustrated in FIG. 8, at 515, a metal is deposited in the cavity 636 to form a metal wall 640 that circumscribes the interface region 624. The metal (e.g., copper) is deposited, for example, with plating (e.g., over plating copper), solder ball attachment or a deposition of solder paste. The metal is deposited to a height that exceeds a height of the resist 628. For instance, if the resist 628 has a height of about 90 μm, the resultant metal wall 640 has a height of about 150 μm. Moreover, the resultant metal wall 640 has a first region that extends from the second side 620 of the die 600 to a top of the cavity 636, and a second region that flows over the resist 628 to form a head with a semicircle shaped cross section. Accordingly, as illustrated, the metal wall 640 has a mushroom shaped cross section.

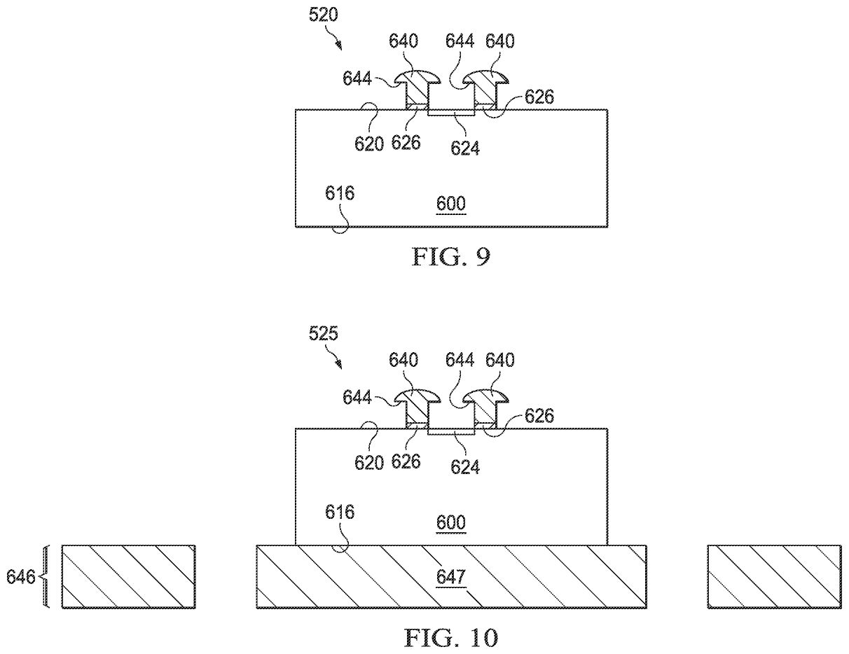

In a fifth stage, as illustrated in FIG. 9, at 520, a remaining portion of the resist 628 and the seed layer 626 are stripped from the second side 620 of the die 600. In some examples, the resist 628 and the seed layer 626 are stripped with chemical wet etching. Also, at 520, the remaining seed layer 626 is etched from the second side 620 of the die 600. Remnants of the seed layer 626 form a portion of the metal wall 640 closest to the second side 620 of the die 600. Accordingly, the metal wall 640 circumscribes the interface region 624 of the die 600. Also, in some examples, a portion 644 of the second region of the metal wall 640 overhangs the interface region 624.

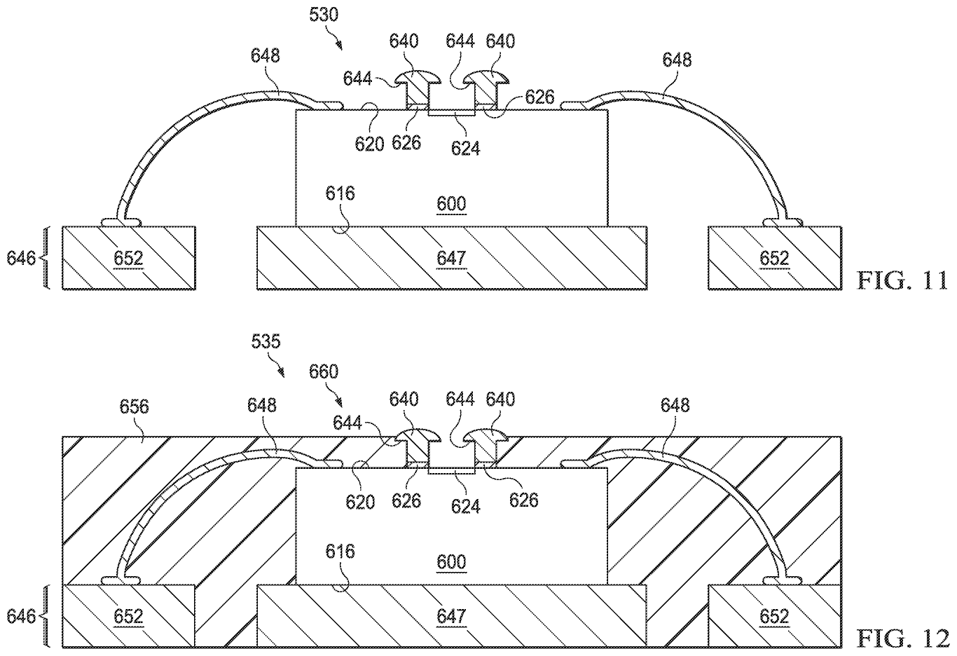

In a sixth stage, as illustrated in FIG. 10, at 525, the die 600 is mounted on an interconnect 646 (e.g., a lead frame). More specifically, the first side 616 of the die 600 is mounted on a die pad 647 of the interconnect 646. In a seventh stage, as illustrated in FIG. 11, at 530, wire bonds 648 are attached to the second side 620 to couple the die 600 to pads 652 (e.g., leads) of the interconnect 646. In an eighth stage, as illustrated in FIG. 12, at 535, a molding 656 is applied to encase the die 600 to form the IC package 660. To apply the molding 656, the molding (e.g., plastic) is heated and flows over the interconnect 646 and the die 600. However, the molding 656 is prevented from flowing over the second region of the metal wall 640. In particular, a thickness of the molding between the second side 620 of the die 600 and a top of the molding 656 is less than a height of the metal wall 640. Accordingly, the molding 656 is prevented from flowing over the interface region 624 of the die 600. Accordingly, the molding 656 does not obstruct a view of the environment for the interface region 624 of the die 600.

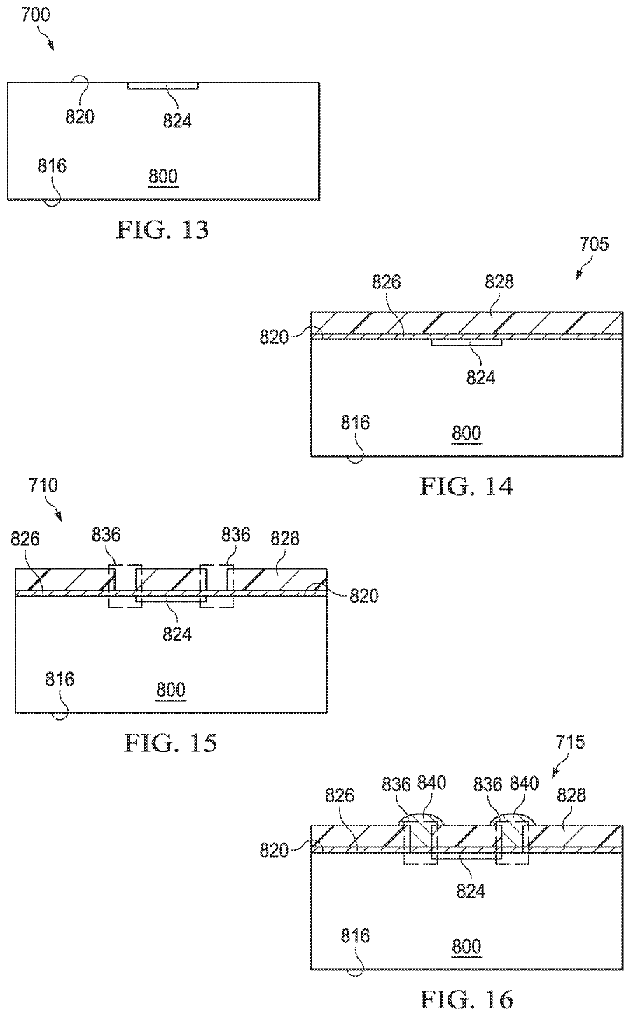

FIGS. 13-21 illustrate an alternative method for forming an IC package, such as the IC package 300 of FIG. 3. For purposes of simplification of explanation, FIGS. 13-21 employ the same reference numbers to denote the same structure.

In a first stage, as illustrated in FIG. 13, at 700, a die 800 is provided. In some examples, the die 800 is implemented with the die 104 of FIGS. 1-4. More particularly, a first side 816 of the die 800 is mountable on a die pad of an interconnect (e.g., a lead frame). A second side 820 of the die 800 includes an interface region 824 configured to interact with an environment of the IC package. In some examples, the die 800 is a sensor, and the interface region 824 enables the die 800 to sense the environment. In other examples, the interface region 824 provides light to the environment.

In a second stage, as illustrated in FIG. 14, at 705, a seed layer 826 for growing metal (e.g., copper) is deposited to the second side 820 of the die 800 (e.g., with a spudder deposition operation). Additionally at 705 a layer of resist 828 (e.g., photoresist) is applied to the second side 820 of the die 800 to overlay the seed layer 826. In a third stage, as illustrated in FIG. 15 at 710, the resist 828 is etched to form a cavity 836 for a metal wall. The cavity 836 circumscribes the interface region 824. Thus, in some examples, the cavity 836 has a circular shape.

In a fourth stage, as illustrated in FIG. 16, at 715, a metal is deposited in the cavity 836 to form a metal wall 840 that circumscribes the interface region 824. The metal (e.g., copper) is deposited, for example, with a solder ball attachment or a deposition of solder paste. The metal is deposited to a height that exceeds a height of the resist 828. For instance, if the resist 828 has a height of about 90 μm, the resultant metal wall 840 has a height of about 150 μm. Moreover, the resultant metal wall 840 has a first region that extends from the second side 820 of the die 800 to a top of the cavity 836, and a second region that flows over the resist 828 to form a head with a semicircle shaped cross section. Accordingly, as illustrated, the metal wall 840 initially has a mushroom shaped cross section.

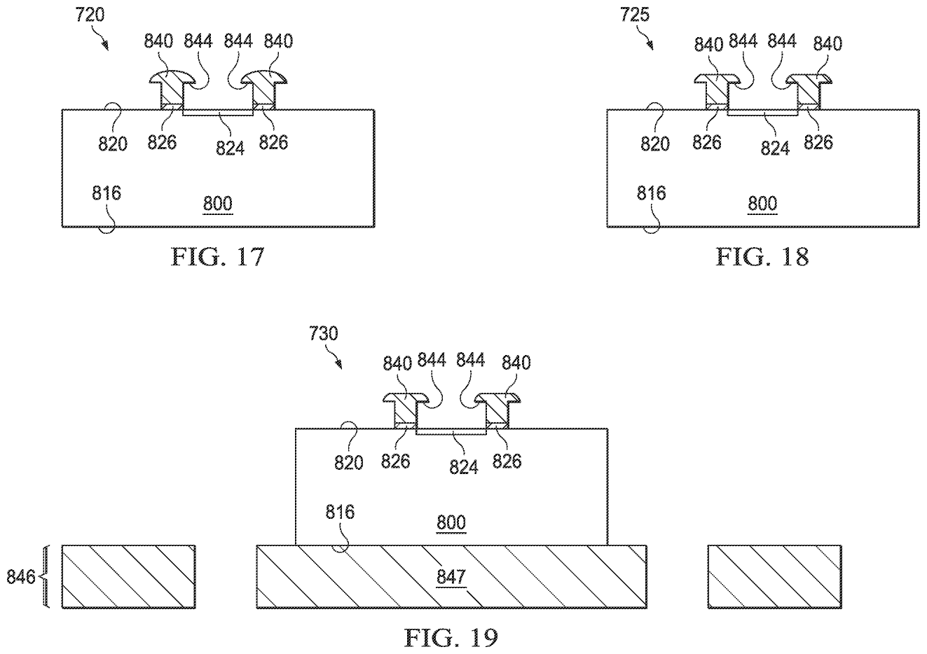

In a fifth stage, as illustrated in FIG. 17, at 720, a remaining portion of the resist 828 is stripped from the second side 820 of the die 800. In some examples, the resist 828 is stripped with a chemical wet etch. Also, at 720, the remaining seed 826 is etched from the second side 820 of the die 800. Remnants of the seed layer 826 form a portion of the metal wall 840 closest to the second side 820 of the die 800. Accordingly, the metal wall 840 circumscribes the interface region 824 of the die 800. Also, in some examples, a portion 844 of the second region of the metal wall 840 overhangs the interface region 824.

In a sixth stage, as illustrated in FIG. 18, at 725, the second region of the metal wall 840 is cut in a fly-cutting operation (e.g., with a laser or a saw). In some examples, about 20 μm of the second region of the metal wall 840 is cut at 725, such that the resultant metal wall 840 has a height of about 130 μm (e.g., about 90 μm in the first region and about 40 μm in the second region). As a result, as illustrated, the metal wall 840 has a nail shaped cross section.

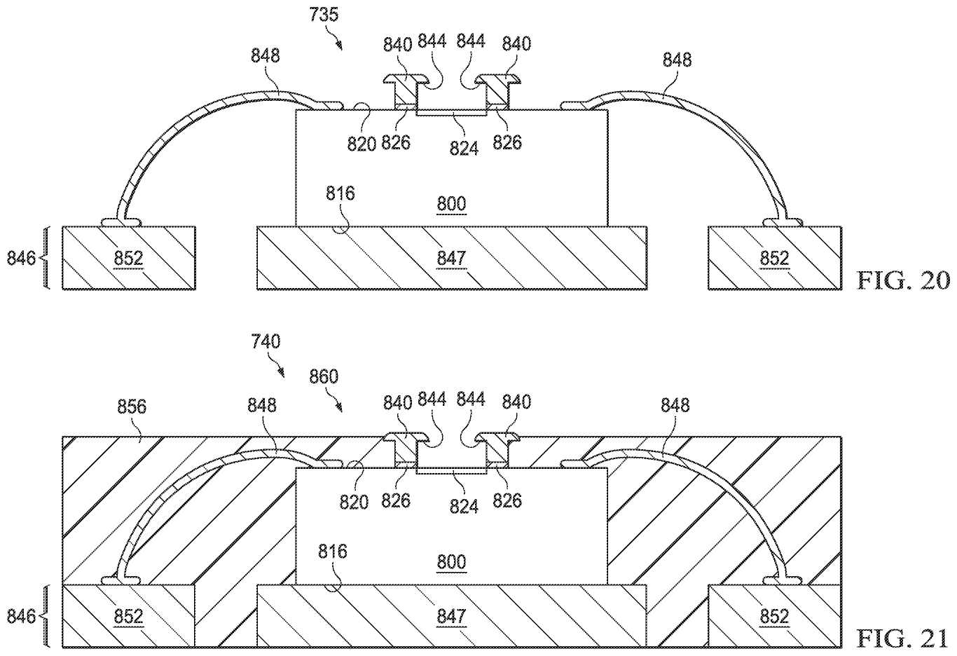

In a seventh stage, as illustrated in FIG. 19, at 730 the die 800 is mounted on an interconnect 846 (e.g., a lead frame). More specifically, at 730, the first side 816 of the die 800 is mounted on a die pad 847 of the interconnect 846. In an eighth stage, as illustrated in FIG. 20, at 735, wire bonds 848 are attached to the second side 820 to couple the die 800 to pads 852 (e.g., leads) of the interconnect 846. In a ninth stage, as illustrated in FIG. 21, at 740, a molding 856 is applied to encase the die 800 to form the IC package 860. To apply the molding 856, the molding (e.g., plastic) is heated and flows over the interconnect 846 and the die 800. However, the molding 856 is prevented from flowing over the second region of the metal wall 840. In particular, a thickness of the molding between the second side 820 of the die 800 and a top of the molding 656 is less than a height of the metal wall 840. Accordingly, the molding 856 is prevented from flowing over the interface region 824 of the die 800. Accordingly, the molding 856 does not obstruct a view of the environment for the interface region 824 of the die 800.

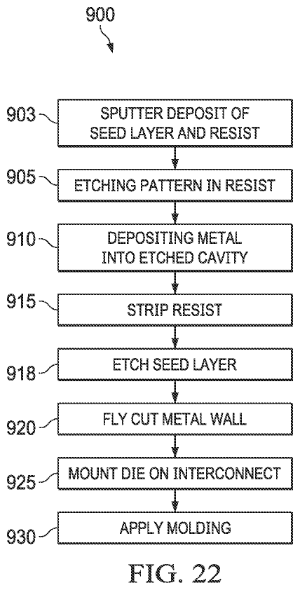

FIG. 22 illustrates a flowchart of an example method 900 for forming an IC package, such as the IC package 100 of FIG. 1 or the IC package 300 of FIG. 3. At 903, in a sputter deposition operation, a seed layer is deposited on a surface of a die (e.g., the die 600 of FIG. 6). Additionally, at 903, a layer of resist (e.g., the resist 628 of FIG. 6) is also deposited on the surface of the die. At 905, a pattern is etched in the layer of resist overlaying the surface of a die. The pattern includes an etched cavity (e.g., the cavity 636 of FIG. 7) circumscribing an interface region (e.g., the interface region 624 of FIG. 7) on the surface of the die. The etched cavity extends from the surface of the die to a first height.

At 910, metal is deposited in the etched cavity to form a metal wall (e.g., the metal wall 640 of FIG. 1) circumscribing the interface region of the die. The metal wall includes a first region having a first width, the first region extending from the surface of the die to the first height, and a second region stacked on the first region, the second region having a second width greater than the first width and the second region extending from the first height to a second height. Accordingly, at 910, the metal wall has a mushroom shaped cross section. At 915, the resist is stripped from the surface of the die (e.g., with a chemical etching process). At 918, the seed layer is etched from the surface of the die.

At 920, the second region of the metal wall is fly cut, such that the metal wall has a nail shaped cross section. In some examples, the operation at 920 is omitted. At 925, the die is mounted on an interconnect (e.g., the interconnect 108 of FIGS. 1-4). More particularly, the die is mounted on a die pad of the interconnect. In some examples at 925, wire bonds (e.g., the wire bonds 132 of FIG. 1) are attached to the surface of the die an pads of the interconnect to electrically couple the die with the pads of the interconnect. At 930 a mold is applied to the interconnect and the die to encase the die. However, the mold does not flow over the metal wall, such that the interface region is exposed to an environment, and the mold extends from the surface of the die to a height less than the height of the metal wall.

Modifications are possible in the described embodiments, and other embodiments are possible, within the scope of the claims.

What is claimed is:

1. An integrated circuit (IC) package comprising:
a die comprising a interface region situated on a surface of the die, wherein the interface region is configured to be exposed to an environment of the IC package;
a metal wall mounted on the surface of the die that circumscribes the interface region and extends from the surface of the die to a wall height, the metal wall comprising a first region and a second region that is stacked on the first region, the first region having a first thickness and the second region having a second thickness, the second thickness being greater than the first thickness; and
a molding encasing a remaining portion of the die, wherein the molding has a height that extends from the surface of the die to a level that is less than the wall height of the metal wall.

2. The IC package of claim 1, wherein the metal wall is formed of copper.

3. The IC package of claim 1, wherein the molding extends to a height that is about equal to a height of the first region of the metal wall.

4. The IC package of claim 1, wherein the molding extends to a height that is greater than a height of the first region of the metal wall.

5. The IC package of claim 1, wherein a portion of the second region of the metal wall overhangs the interface region of the die.

6. The IC package of claim 1, wherein the second region of the metal wall has a semicircle cross section.

7. The IC package of claim 1, wherein the second region of the metal wall has a planer surface on an end distal to the die.

8. The IC package of claim 1, wherein the surface of the die is a first surface, the IC package further comprising:
an interconnect, wherein a second surface of the die is mounted on a die pad of the interconnect; and
a wire bond that is coupled to the first surface of the die and to a pad of the interconnect.

9. The IC package of claim 1, wherein the metal wall forms a ring.

10. The IC package of claim 9, wherein the ring has a diameter of 55-60 micrometers.

11. A method for forming an integrated circuit (IC) package, the method comprising:
etching a pattern in a layer of resist overlaying a surface of a die, wherein the pattern includes an etched cavity circumscribing an interface region on the surface of the die, the etched cavity extending from the surface of the die to a first height;
depositing metal in the etched cavity to form a metal wall circumscribing the interface region of the die, wherein the metal wall comprises a first region having a first width, the first region extending from the surface of the die to the first height, and a second region stacked on the first region, the second region having a second width greater than the first width and the second region extending from the first height to a second height;
stripping the resist from the surface of the die; and
applying a mold to encase the die, such that the interface region is exposed to an environment, and the mold extends from the surface of the die to a height less than the second height of the metal wall.

12. The method of claim 11, wherein the metal wall has a ring shape.

13. The method of claim 12, wherein the metal wall has a diameter of 55-60 micrometers.

14. The method of claim 11, wherein the second region of the metal wall has a semicircle cross section.

15. The method of claim 14, wherein depositing the metal comprises plating copper in the etched cavity.

16. The method of claim 11, wherein depositing the metal comprises one of attaching a solder ball in the etched cavity and depositing solder paste in the etched cavity.

17. The method of claim 16, further comprising, fly cutting, prior to applying the molding, the second region of the metal wall, such that a surface of the metal wall distal from the surface of the die is planer.

18. The method of claim 11, wherein a portion of the second region of the metal wall overhangs the interface region of the die.

19. The method of claim 11, further comprising:
depositing a seed layer for metal on the surface of the die;
depositing the resist on the seed layer; and
etching the seed layer prior to applying the molding.

20. The method of claim 11, further comprising attaching a wire bond to the surface of the die and to a pad of an interconnect to electrically couple the surface of the die to the pad of the interconnect.
